(19) United States
(12) Patent Application Publication
(10) Pub. No.: US 2012/0064687 A1
(43) Pub. Date: Mar. 15, 2012

(54) METHOD OF MANUFACTURING SEMICONDUCTOR DEVICE

(75) Inventors: Yoshiyuki Kondo, Yokohama-Shi (JP); Kimitoshi Okano, Yokohama-Shi (JP); Shigeru Kawanaka, Yokohama-Shi (JP)

(73) Assignee: KABUSHIKI KAISHA TOSHIBA, Tokyo (JP)

(21) Appl. No.: 13/227,622

(22) Filed: Sep. 8, 2011

(30) Foreign Application Priority Data
Sep. 9, 2010 (JP) 2010-202109

(51) Int. Cl. H01L 21/8234; H01L 21/336

(52) U.S. Cl. 438/303; 257/E21.438; 257/E21.625

(57) ABSTRACT

According to one embodiment, a method of manufacturing a semiconductor device includes: forming a gate electrode on a substrate via a gate dielectric film; forming a first insulating film on the gate electrode, the first insulating film having a first groove in a central region of the first insulating film; and forming a halo region in the substrate below a side surface of the gate electrode, by injecting an impurity into the substrate through the first insulating film.

### CROSS REFERENCE TO RELATED APPLICATIONS

This application is based upon and claims the benefit of priority from prior Japanese Patent Application No. 2010-202109, filed on Sep. 9, 2010, the entire contents of which are incorporated herein by reference.

### FIELD

Embodiments of the present invention relate to a method of manufacturing a semiconductor device.

### BACKGROUND

In the related art, there has been disclosed a technology for forming halo regions which suppresses a short channel effect of a transistor by means of ion implantation (ion implantation in a direction at an angle to a direction perpendicular to the surface of a substrate).

As for transistors for memory cells, when forming halo regions of the transistors arranged at a small interval, in order to implant impurities not to be blocked by adjacent transistors, it is necessary to significantly reduce an implantation angle based on a vertical direction. Specifically, when a cap film on a gate electrode is thick, since an aspect ratio of a space between adjacent transistors is large, an ion implantation angle is small.

In that case, since an impurity implantation region is set apart from the gate electrode, it is necessary to diffuse implanted impurities up to below the gate electrode in a transverse direction over a long distance. This makes it difficult to form a halo region having an appropriate concentration profile capable of suppressing a short channel effect. Furthermore, since the implanted impurities need to be diffused over a long distance, the amount of impurities to be implanted is large, which increases the manufacturing cost.

### BRIEF DESCRIPTION OF THE DRAWINGS

FIG. 1 is a vertical sectional view of a semiconductor device according to a first embodiment;

FIGS. 2A to 2O are vertical sectional views illustrating a manufacturing process of a semiconductor device according to the first embodiment;

FIG. 3 is a vertical sectional view of a semiconductor device according to a second embodiment;

FIGS. 4A to 4O are vertical sectional views illustrating a manufacturing process of a semiconductor device according to the second embodiment;

FIG. 5 is a vertical sectional view of a semiconductor device according to a third embodiment;

FIG. 6 is a plan view of a semiconductor device according to the third embodiment; and

FIGS. 7A (a) to 7C (b) are a vertical sectional view and a plan view illustrating a manufacturing process of a semiconductor device according to the third embodiment, respectively.

### DETAILED DESCRIPTION

In one embodiment, a method of manufacturing a semiconductor device includes: forming a gate electrode on a substrate via a gate dielectric film; forming a first insulating film on the gate electrode, the first insulating film having a first groove in a central region of the first insulating film; and forming a halo region in the substrate below a side surface of the gate electrode, by injecting an impurity into the substrate through the first insulating film.

### First Embodiment

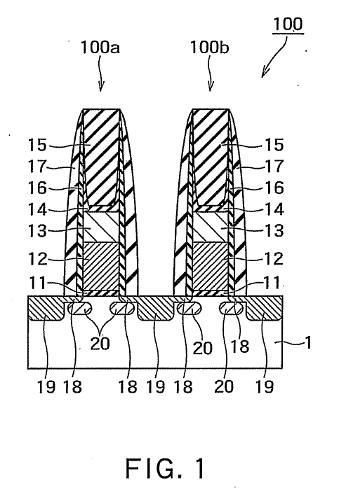

FIG. 1 is a vertical sectional view of a semiconductor device 100 according to a first embodiment. The semiconductor device 100 includes a semiconductor substrate 1, and transistors 100a and 100b on the semiconductor substrate 1.

The semiconductor substrate 1 is made of Si-based crystal such as Si crystal.

The transistors 100a and 100b, for example, include transistors for memory cells arranged at a narrow interval.

As illustrated in FIG. 1, the transistors 100a and 100b include a gate dielectric film 11, a semiconductor electrode 12, a metal electrode 13, a protective film 14, a cap film 15, an offset spacer 16, a sidewall spacer 17, extension regions 18 of a source/drain region, and high concentration regions 19 of the source/drain region, respectively. The semiconductor electrode 12 is formed on the semiconductor substrate 1 via the gate dielectric film 1, the metal electrode 13 is formed on the semiconductor electrode 13, and the cap film 15 is formed on the metal electrode 13 via the protective film 14.

The gate dielectric film 11, for example, is made of a dielectric material such as SiO₂, SiON, or High-K material.

The semiconductor electrode 12 and the metal electrode 13 constitute gate electrodes of each of the transistors 100a and 100b, respectively. The transistors 100a and 100b may include only one of the semiconductor electrode 12 and the metal electrode 13.

The semiconductor electrode 12, for example, is made of Si-based polycrystal such as polycrystalline Si including conductive impurity. Furthermore, instead of the semiconductor electrode 12, a metal electrode may be used.

The metal electrode 13 is made of a metal such as W, Al or Cu. Furthermore, the metal electrode 13 may be made of a metal (e.g. a silicide) formed by siliciding the whole or an upper portion of the semiconductor electrode 12.

The protective film 14, the cap film 15, the offset spacer 16, and the sidewall spacer 17 are made of insulating materials such as SiN. The materials of the protective film 14, the cap film 15, the offset spacer 16, and the sidewall spacer 17 may be equal to one another or different from one another.

The protective film 14 is in contact with the upper surface of the metal electrode 13 and the inner side surface of the offset spacer 16. The protective film 14 protects the upper surface of the metal electrode 13.

The bottom surface and the side surface of the cap film 15 are in contact with the protective film 14.

The offset spacer 16 is formed on the lateral side surfaces of the gate dielectric film 11, the semiconductor electrode 12, the metal electrode 13, and the protective film 14.

The sidewall spacer 17 is formed on the outer side surface of the offset spacer 16.

The extension regions 18 and the high concentration regions 19 of the source/drain region include conductive impurity implanted into the semiconductor substrate 1. In the extension region 18, the concentration of the conductive impurity is low and the conductive impurity is thinly distributed. In the high concentration region 19, the concentration of the conductive impurity is high and the conductive impurity is thickly distributed. The extension region 18 is adjacent to the gate dielectric film 11, as compared with the high concentration region 19.

As illustrated in FIG. 1, the extension regions 18 and the high concentration regions 19 between the transistor 100a and the transistor 100b may be shared by the transistor 100a and the transistor 100b.

Moreover, halo regions 20 are formed in the semiconductor substrate 1. The halo region 20 includes conductive impurity which is different from conductive impurity constituting the extension region 18 and the high concentration region 19, thereby suppressing a short channel, effect. The halo region 20 is mainly formed in a region under the extension region 18 in the semiconductor substrate 1.

Hereinafter, an example of a method of manufacturing the semiconductor device 100 according to the present embodiment will be described.

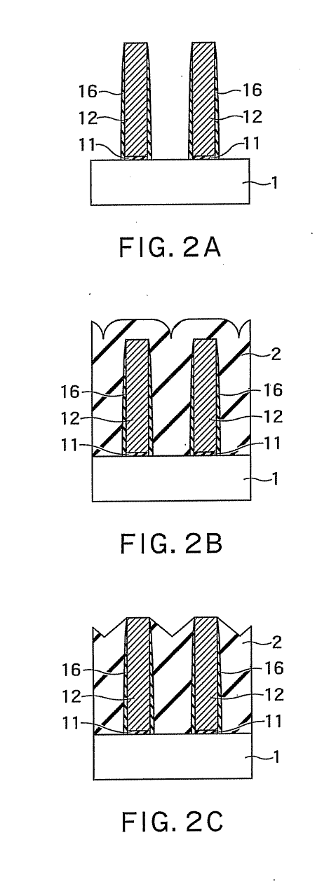

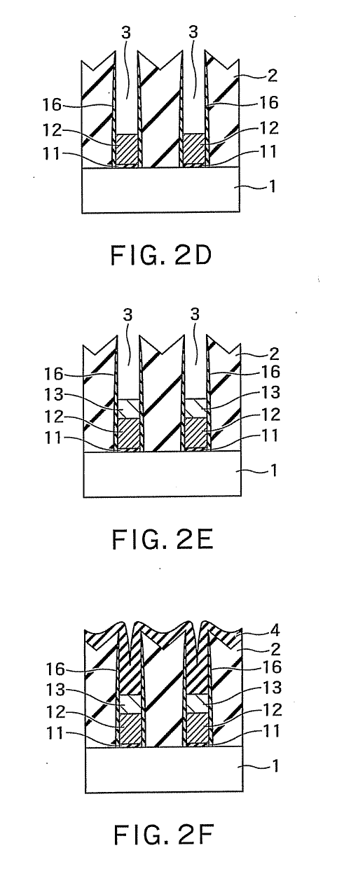

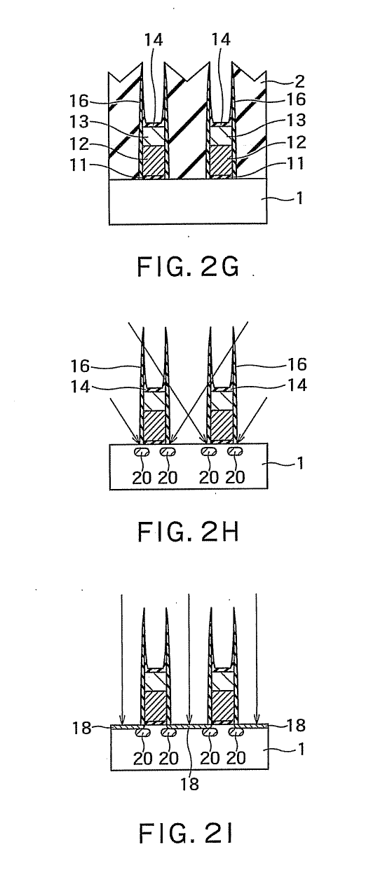

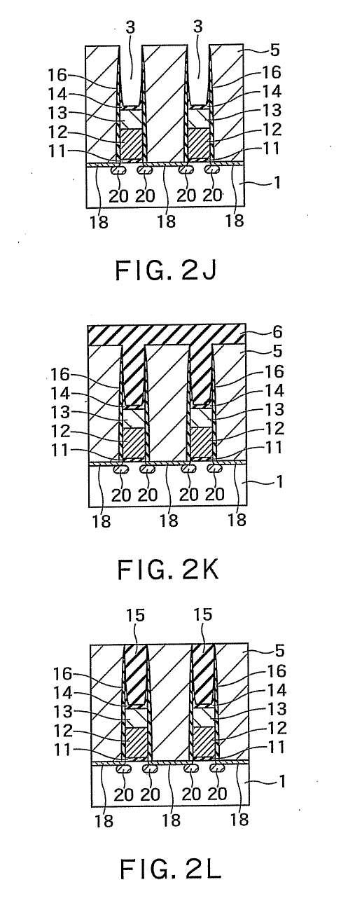

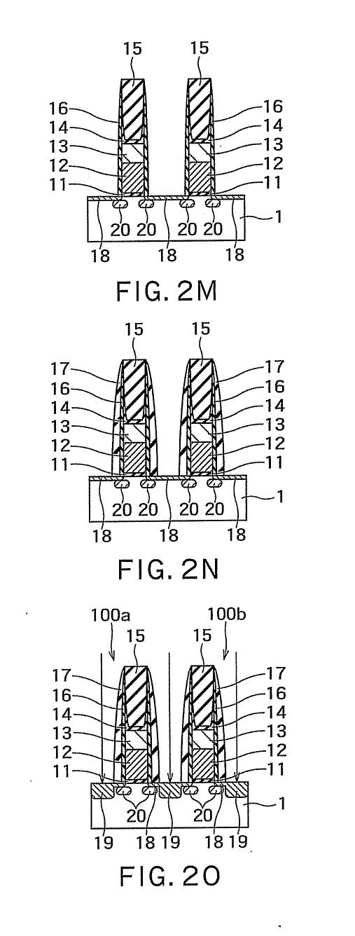

FIGS. 2A to 2O are vertical sectional views illustrating a manufacturing process of the semiconductor device 100 according to the first embodiment.

First, as illustrated in FIG. 2A, the gate dielectric film 11, the semiconductor electrode 12, and the offset spacer 16 are formed on the semiconductor substrate 1.

An example of a method of forming the gate dielectric film 11, the semiconductor electrode 12, and the offset spacer 16 will be described below. First, the surface of the semiconductor substrate 1 is thermally oxidized to form a SiO₂ film. Next, a polycrystalline Si film is formed on the SiO₂ film using a chemical vapor deposition (CVD) method. Here, the polycrystalline Si film is sufficiently thick as compared with the SiO₂ film, and for example, has a thickness of 300 nm. Next, the polycrystalline Si film and the SiO₂ film are patterned using a lithography method and a reactive ion etching (RIE) method, thereby forming the semiconductor electrode 12 and the gate dielectric film 11, respectively. Then, a SiN film is formed on the entire surface of the semiconductor substrate 1 using a CVD method. Thereafter, the SiN film is etched using an RIE method to form the offset spacer 16 on the lateral side surface of the semiconductor electrode 12. The width in the gate length direction of the bottom portion of the offset spacer 16, for example, is 5 nm.

Next, as illustrated in FIG. 2B, SiO₂ or the like is deposited on the entire surface of the semiconductor substrate 1 using a CVD method, thereby forming an insulating film 2. The insulating film 2 is formed to cover the semiconductor electrode 12 and the offset spacer 16.

Then, as illustrated in FIG. 2C, the insulating film 2 is etched using an RIE method, so that the upper surface of the semiconductor electrode 12 is exposed. As a consequence, the insulating film 2 is positioned around the semiconductor electrode 12 and the offset spacer 16 to fill the semiconductor electrode 12 and the offset spacer 16.

Thereafter, as illustrated in FIG. 2D, the semiconductor electrode 12 is selectively etched using an RIE method, so that the height of the semiconductor electrode 12 is reduced. At this time, the semiconductor electrode 12 is etched under conditions of etching selectivity relative to the insulating film 2 and the offset spacer 16.

In this way, the height of the semiconductor electrode 12 is lowered as compared with a portion of the insulating film 2, which is adjacent to the semiconductor electrode 12, and a groove 3 is formed on the semiconductor electrode 12. The groove 3 is formed by the offset spacer 16 and the semiconductor electrode 12. The bottom surface of the groove 3 is the upper surface of the semiconductor electrode 12, and the side surface of the groove 3 is the upper portion of the inner side surface of the offset spacer 16.

Next, as illustrated in FIG. 2E, W is selectively deposited on the semiconductor electrode 12 using a selective W-CVD method.

Then, as illustrated in FIG. 2F, SiN is deposited on the entire surface of the semiconductor substrate 1 using a CVD method, thereby forming an insulating film 4. The insulating film 4 covers the bottom surface and the side surface of the groove 3, that is, the upper surface of the metal electrode 13 and the inner side surface of the offset spacer 16. Furthermore, the insulating film 4 is formed under conditions of poor step coverage, has an irregular thickness, and does not fill the groove 3.

Next, as illustrated in FIG. 2G, the insulating film 4 is partially removed using wet etching, so that the insulating film 4 remains on the upper surface of the metal electrode 13 and the inner side surface of the offset spacer 16. In this way, the protective film 14 is obtained. Therefore, the protective film 14 has a groove in the central region of the protective film 14.

Thereafter, the insulating film 2 is removed using wet etching. The insulating film 2 is etched under conditions of etching selectivity relative to the protective film 14 and the offset spacer 16.

Then, as illustrated in FIG. 2H, conductive impurity is implanted into the semiconductor substrate 1 using inclined ion implantation, thereby forming the halo regions 20.

The conductive impurity is injected in the orbit as indicated by arrows of FIG. 2H and passes through the protective film 14 and the offset spacer 16 of a predetermined transistor, thereby forming the halo regions 20 of an adjacent transistor.

For example, conductive impurity having passed through the protective film 14 and the offset spacer 16 of the transistor 100a is implanted into a region of the semiconductor substrate 1, which is positioned below the side surface of the semiconductor electrode 12 of the transistor 100b facing the transistor 100a, thereby forming the halo regions 20 of the transistor 100b. Furthermore, conductive impurity having passed through the protective film 14 and the offset spacer 16 of the transistor 100b is implanted into a region of the semiconductor substrate 1, which is positioned below the side surface of the semiconductor electrode 12 of the transistor 100a facing the transistor 100b, thereby forming the halo regions 20 of the transistor 100a.

In addition, as with the conventional method, when forming a halo region using an ion implantation method in the state in which a cap film is formed on a gate electrode, in order to implant conductive impurity at an angle not blocked by the cap film, it is necessary to significantly reduce an implantation angle (an angle based on a direction perpendicular to the surface of the substrate). Therefore, when the cap film is thick and an aspect ratio (height/width) of a space between adjacent transistors is large, it is difficult to form a halo region having an appropriate concentration profile.

In the present embodiment, since the protective film 14 and the offset spacer 16 are sufficiently thin and allow impurity to pass therethrough, an ion implantation angle does not depend on the heights of the protective film 14 and the offset spacer 16. That is, the ion implantation angle does not depend on the height of the cap film 15. Consequently, even when the cap film 15 is thick and an aspect ratio of a space between adjacent transistors such as the transistors 100a and 100b is large, it is possible to form the halo regions 20 having an appropriate concentration profile.

For example, when the thickness of the semiconductor electrode 12 is 80 nm, the thickness of the metal electrode 13 is 50 nm, and the distance in the gate length direction between the semiconductor electrode 12 of the transistor 100a and the semiconductor electrode 12 of the transistor 100b is 50 nm, an implantation angle based on a direction perpendicular to the surface of the semiconductor substrate 1 is substantially equal to 21° (arctan(50/130)).

Then, as illustrated in FIG. 2I, conductive impurity is injected into the semiconductor substrate 1 using an ion implantation method, thereby forming the extension regions 18. The impurity is injected along a direction approximately perpendicular to the surface of the semiconductor substrate 1. In addition, before forming the halo regions 20, the extension regions 18 may be formed.

Next, as illustrated in FIG. 27, the upper surface of the semiconductor substrate 1 is used as a base and Si-based crystal is epitaxially grown up to a height approximately the same as the offset spacer 16, thereby forming a crystal layer 5. At this time, since the upper surface of the metal electrode 13 is covered by the protective film 14, the Si-based crystal is not grown on the metal electrode 13.

The Si-based crystal constituting the crystal layer 5 is different from the Si-based crystal constituting the semiconductor substrate 1. For example, when the semiconductor substrate 1 is made of Si crystal, the crystal layer 5 uses Si-based crystal other than SiGe crystal or SIC crystal. Consequently, when removing the crystal layer 5 using etching in a subsequent process, the crystal layer 5 is etched under conditions of etching selectivity relative to the semiconductor substrate 1, thereby selectively removing the crystal layer 5.

Then, as illustrated in FIG. 2K, SiN is deposited on the entire surface of the semiconductor substrate 1 using a CVD method, thereby forming an insulating film 6. The insulating film 6 is provided to fill in the groove 3.

Thereafter, as illustrated in FIG. 2L, an insulating film 6 outside the groove 3 is removed using chemical mechanical polishing (CMP), RIE and the like, and a remaining insulating film 6 is formed as the cap film 15.

Next, as illustrated in FIG. 2M, the crystal layer 5 is removed using wet etching. The crystal layer 5 is etched under conditions of etching selectivity relative to the semiconductor substrate 1, and is selectively removed.

Then, as illustrated in FIG. 2N, the sidewall spacer 17 is formed on the outer side surface of the offset spacer 16.

An example of a method of forming the sidewall spacer 17 will be described below. First, a SiN film is formed on the entire surface of the semiconductor substrate 1 using a CVD method. Next, the SiN film is etched using an RIE method, thereby forming the SiN film as the sidewall spacer 17 on the outer side surface of the offset spacer 16.

Thereafter, as illustrated in FIG. 20, conductive impurity is injected into the semiconductor substrate 1 using an ion implantation method, thereby forming the high concentration regions 19. The impurity is injected along a direction approximately perpendicular to the surface of the semiconductor substrate 1. As a consequence, the transistors 100a and 100b are obtained. In addition, a silicide layer may be formed on the high concentration regions 19.

### Second Embodiment

The second embodiment is substantially the same as the first embodiment, except that no offset spacer 16 is formed. In addition, parts the same as the first embodiment will not be described or simplified.

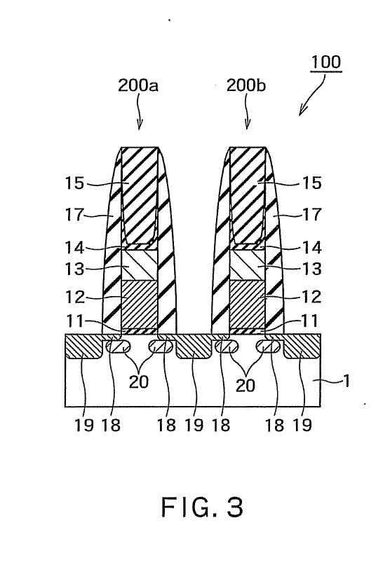

FIG. 3 is a vertical sectional view of a semiconductor device 200 according to the second embodiment. The semiconductor device 200 includes a semiconductor substrate 1, and transistors 200a and 200b on the semiconductor substrate 1.

The transistors 200a and 200b, for example, include transistors for memory cells arranged at a narrow interval.

Each of the transistors 200a and 200b includes a semiconductor electrode 12 formed on the semiconductor substrate 1 through a gate dielectric film 11, a metal electrode 13 on the semiconductor electrode 12, a protective film 14 on the metal electrode 13, a cap film 15 on the protective film 14, a sidewall spacer 17, extension regions 18 of a source/drain region, and high concentration regions 19 of the source/drain region. The transistors 200a and 200b are different from the transistors 100a and 100b of the first embodiment, and include no offset spacer 16.

The protective film 14 is in contact with the upper surface of the metal electrode 13 and the inner side surface of the sidewall spacer 17. The protective film 14 protects the upper surface of the metal electrode 13.

The sidewall spacer 17 is formed on the lateral side surfaces of the gate dielectric film 11, the semiconductor electrode 12, the metal electrode 13, and the protective film 14.

Hereinafter, an example of a method of manufacturing the semiconductor device 200 according to the present embodiment will be described.

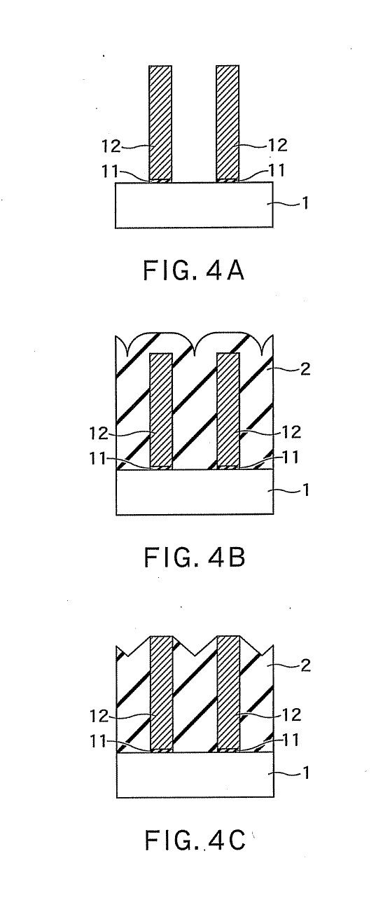

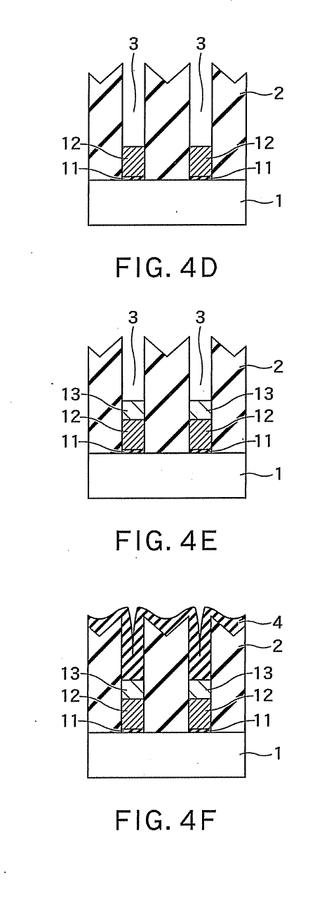

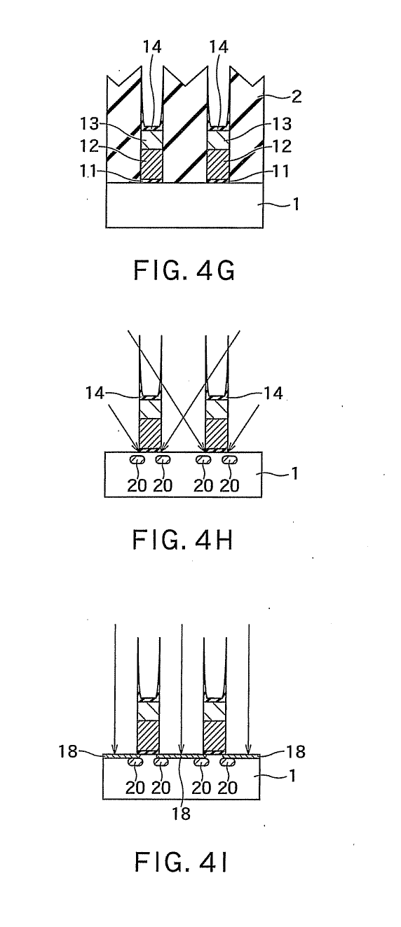

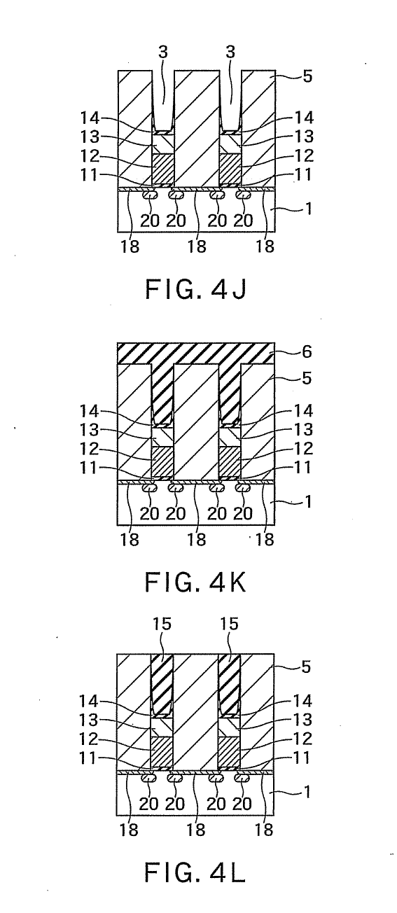

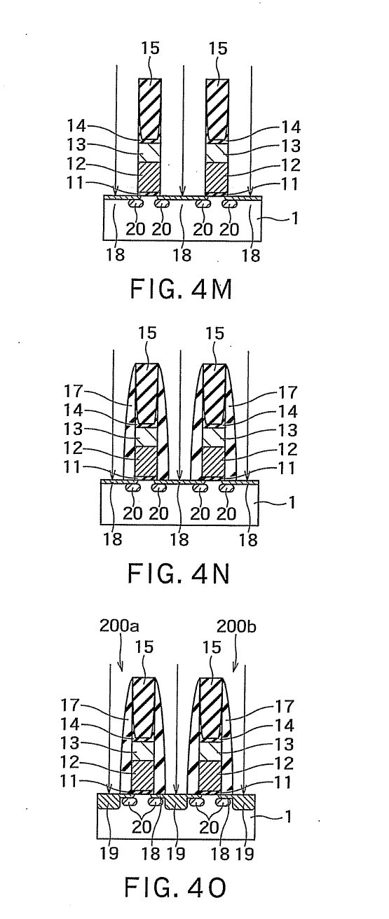

FIGS. 4A to 4O are vertical sectional views illustrating a manufacturing process of the semiconductor device 200 according to the second embodiment.

First, as illustrated in FIG. 4A, the gate dielectric film 11 and the semiconductor electrode 12 are formed on the semiconductor substrate 1.

Next, as illustrated in FIG. 4B, SiO₂ and the like are deposited on the entire surface of the semiconductor substrate 1 using a CVD method, thereby forming an insulating film 2. The insulating film 2 is formed to cover the semiconductor electrode 12.

Then, as illustrated in FIG. 4C, the insulating film 2 is etched using an RIE method, so that the upper surface of the semiconductor electrode 12 is exposed. As a consequence, the insulating film 2 is positioned around the semiconductor electrode 12 to fill the semiconductor electrode 12.

Thereafter, as illustrated in FIG. 4D, the semiconductor electrode 12 is selectively etched using an RIE method, so that the height of the semiconductor electrode 12 is reduced. At this time, the semiconductor electrode 12 is etched under conditions of etching selectivity relative to the insulating film 2.

In this way, the height of the semiconductor electrode 12 is lowered as compared with a portion of the insulating film 2, which is adjacent to the semiconductor electrode 12, and a groove 3 is formed on the semiconductor electrode 12. The bottom surface of the groove 3 is the upper surface of the semiconductor electrode 12, and the side surface of the groove 3 is the upper portion of the inner side surface of the insulating film 2.

Next, as illustrated in FIG. 4E, W is selectively deposited on the semiconductor electrode 12 using a selective W-CVD method, thereby forming the metal electrode 13.

Then, as illustrated in FIG. 4F, SiN is deposited on the entire surface of the semiconductor substrate 1 using a CVD method, thereby forming an insulating film 4. The insulating film 4 covers the bottom surface and the side surface of the groove 3, that is, the upper surface of the metal electrode 13 and the inner side surface of the insulating film 2. Furthermore, the insulating film 4 is formed under conditions of poor step coverage, has an irregular thickness, and does not fill the groove 3.

Next, as illustrated in FIG. 4G, the insulating film 4 is partially removed using wet etching, so that the insulating film 4 remains on the upper surface of the metal electrode 13 and the inner side surface of the insulating film 2. In this way, the protective film 14 is obtained.

Thereafter, the insulating film 2 is removed using wet etching. The insulating film 2 is etched under conditions of etching selectivity relative to the protective film 14.

Then, as illustrated in FIG. 4H, conductive impurity is implanted into the semiconductor substrate 1 using inclined ion implantation, thereby forming the halo regions 20.

The conductive impurity is injected in the orbit as indicated by arrows of FIG. 4H and passes through the protective film 14 of a predetermined transistor, thereby forming the halo regions 20 of an adjacent transistor.

For example, conductive impurity having passed through the protective film 14 of the transistor 200a is implanted into a region of the semiconductor substrate 1, which is positioned below the side surface of the semiconductor electrode 12 of the transistor 200b facing the transistor 200a, thereby forming the halo regions 20 of the transistor 200b. Furthermore, conductive impurity having passed through the protective film 14 of the transistor 200b is implanted into a region of the semiconductor substrate 1, which is positioned below the side surface of the semiconductor electrode 12 of the transistor 200a facing the transistor 200b, thereby forming the halo regions 20 of the transistor 200a.

In the present embodiment, since the protective film 14 is sufficiently thin and allows impurity to pass therethrough, an ion implantation angle does not depend on the height of the protective film 14. That is, the ion implantation angle does not depend on the height of the cap film 15. Consequently, even when the cap film 15 is thick and an aspect ratio of a space between adjacent transistors such as the transistors 200a and 200b is large, it is possible to form the halo regions 20 having an appropriate concentration profile.

Then, as illustrated in FIG. 4I, conductive impurity is injected into the semiconductor substrate 1 using an ion implantation method, thereby forming the extension regions 18.

Next, as illustrated in FIG. 43, the upper surface of the semiconductor substrate 1 is used as a base and Si-based crystal is epitaxially grown up to a height approximately the same as the protective film 14, thereby forming a crystal layer 5.

Then, as illustrated in FIG. 4K, SiN is deposited on the entire surface of the semiconductor substrate 1 using a CVD method, thereby forming an insulating film 6. The insulating film 6 is filled in the groove 3.

Thereafter, as illustrated in FIG. 4L, an insulating film 6 outside the groove 3 is removed using CMP, and a remaining insulating film 6 is formed as the cap film 15.

Next, as illustrated in FIG. 4M, the crystal layer 5 is removed using wet etching. The crystal layer 5 is etched under conditions of etching selectivity relative to the semiconductor substrate 1, and is selectively removed.

Then, as illustrated in FIG. 4N, the sidewall spacer 17 is formed on the lateral side surfaces of the gate dielectric film 11, the semiconductor electrode 12, the metal electrode 13, the protective film 14, and the cap surface 15.

Thereafter, as illustrated in FIG. 4O, conductive impurity is injected into the semiconductor substrate 1 using an ion implantation method, thereby forming the high concentration regions 19. As a consequence, the transistors 200a and 200b are obtained. In addition, a silicide layer may be formed on the high concentration regions 19.

### Third Embodiment

The third embodiment is substantially the same as the first embodiment, except that a self-aligned contact is formed between the transistor 100a and the transistor 100b. In addition, parts the same as the first embodiment will not be described or simplified.

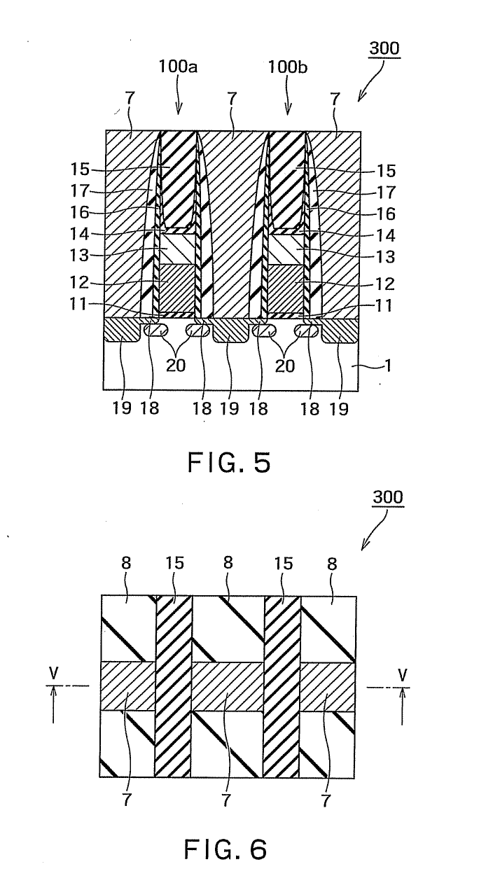

FIG. 5 is a vertical sectional view of a semiconductor device 300 according to the third embodiment. FIG. 6 is a plan view of the semiconductor device 300. The section illustrated in FIG. 5 corresponds to the vertical section taken along line V-V of FIG. 6.

The semiconductor device 300 includes a semiconductor substrate 1, and transistors 100a and 100b and an interlayer dielectric film 8 on the semiconductor substrate 1. Instead of the transistors 100a and 100b, the transistors 200a and 200b of the second embodiment may be used.

Extension regions 18 and a high concentration region 19 between the transistors 100a and 100b are shared by the transistors 100a and 100b, and a self-aligned contact 7 is connected to the upper surfaces of the extension regions 18 and the high concentration region 19. The self-aligned contact 7 is in contact with the outer side surface of a sidewall spacer 17 of the transistor 100a and the outer side surface of a sidewall spacer 17 of the transistor 100b.

The self-aligned contact 7 is made of a conductive material such as W. For example, another contact plug is in contact with the upper surface of the self-aligned contact 7.

Here, the self-aligned contact is a contact plug which is formed between two adjacent transistors in a self-alignment manner. As described later, when forming the self-aligned contact, a cap film on a gate electrode should be relatively thickly formed in terms of a manufacturing process thereof. That is, when forming the self-aligned contact, an aspect ratio of a space between adjacent transistors becomes large.

The interlayer dielectric film 8 is made of an insulation material such as SiO₂, and includes the transistors 100a and 100b, and the self-aligned contact 7.

Hereinafter, an example of a method of manufacturing the semiconductor device 300 according to the present embodiment will be described.

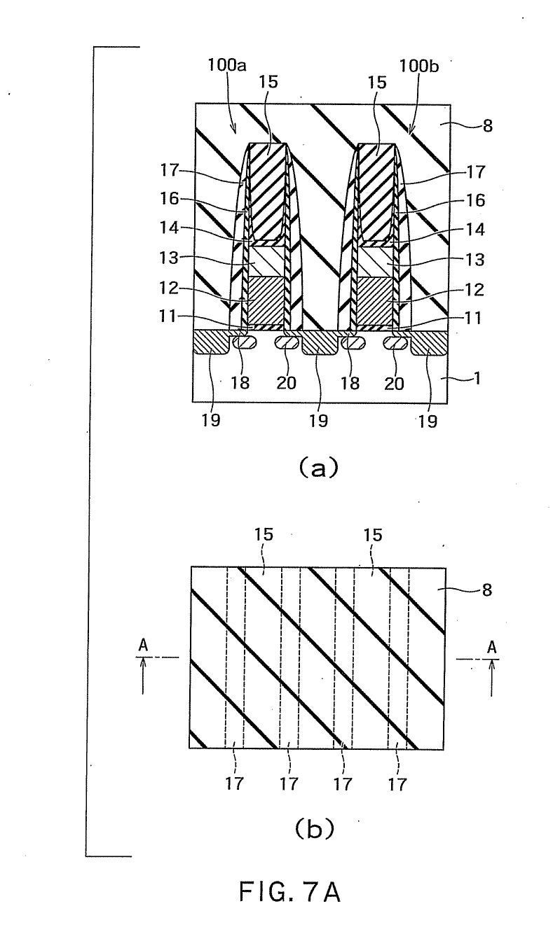

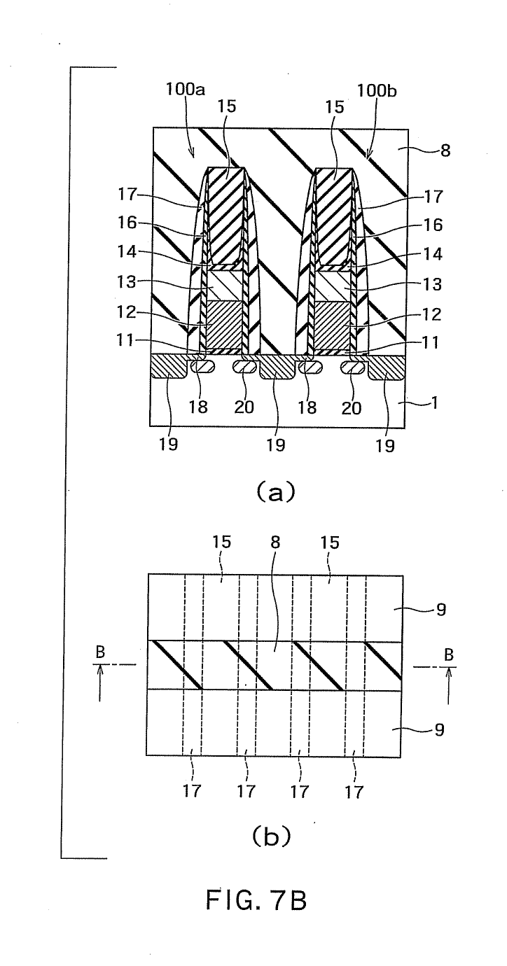

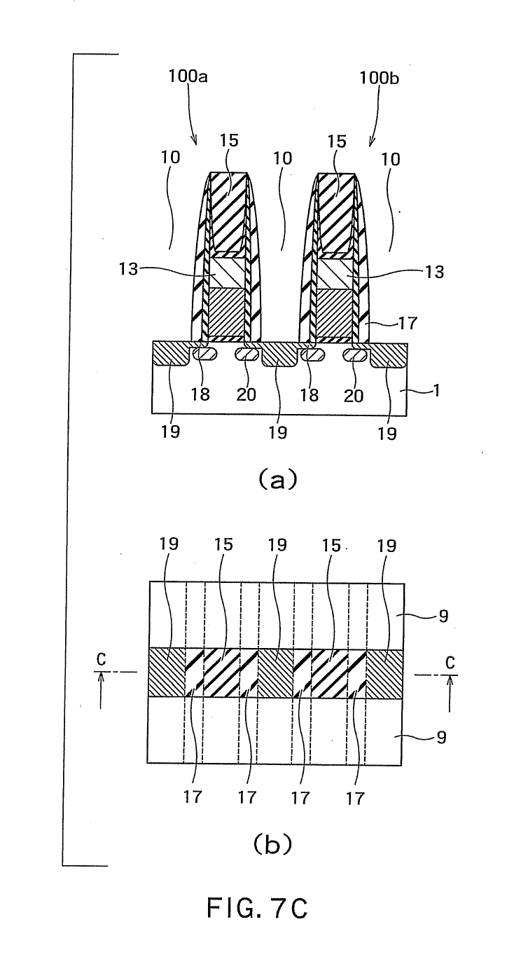

FIGS. 7A (a), 7B (a) and 7C (a) are vertical sectional views illustrating a manufacturing process of the semiconductor device 300 according to the third embodiment. FIG. 7A (b), 7B (b) and 7C (b) are plan views illustrating the manufacturing process of the semiconductor device 300. The section illustrated in FIG. 7A (a) corresponds to the vertical section taken along line A-A of FIG. 7A (b), the section illustrated in FIG. 7B (a) corresponds to the vertical section taken along line B-B of FIG. 7B (b), and the section illustrated in FIG. 7C (a) corresponds to the vertical section taken along line C-C of FIG. 7C (b).

First, processes for forming the transistors 100a and 100b illustrated in FIGS. 2A to 2O are performed in the same manner as the first embodiment.

Next, as illustrated in FIGS. 7A (a) and (b), SiO₂ and the like are deposited on the entire surface of the semiconductor substrate 1 using a CVD method, thereby forming the interlayer dielectric film 8. The interlayer dielectric film 8 is formed to cover the transistors 100a and 100b.

Then, as illustrated in FIGS. 7B (a) and (b), an etching mask 9 is formed on the interlayer dielectric film 8. The etching mask 9 has an opening pattern with a longitudinal direction which is parallel to the gate length directions of the transistors 100a and 100b.

Thereafter, as illustrated in FIGS. 7C (a) and (b), the interlayer dielectric film 8 is etched using the etching mask 9 as a mask through an RIE method, thereby forming a contact hole 10 having a bottom surface through which a part of the high concentration region 19 is exposed.

At this time, the interlayer dielectric film 8 is etched under conditions of etching selectivity relative to the cap film 15 and the sidewall spacer 17. Therefore, since the interlayer dielectric film 8 is removed to a certain degree, the thickness of the interlayer dielectric film 8 is reduced. However, in order to prevent a short circuit between the self-aligned contact 7 and the metal electrode 13, it is necessary to prevent the metal electrode 13 from being exposed due to the removal of the cap film 15. In this regards, even when the cap film 15 is removed when forming the contact hole 10, the cap film 15 should have a relatively large thickness such that the metal electrode 13 is not exposed.

Then, a conductive material such as W is deposited on the entire surface of the semiconductor substrate 1 to fill the contact hole 10, and a conductive material outside the contact hole 10 is removed using a planarization process or etching, so that the self-aligned contact 7 is obtained. As a consequence, the semiconductor device 300 illustrated in FIGS. 5 and 6 is obtained. In addition, a method of forming the self-aligned contact 7 is not limited to the above-mentioned method.

According to the first to third embodiments, even when the cap film on the gate electrode is thick and an aspect ratio of a space between adjacent transistors is large, it is possible to form a halo region having an appropriate concentration profile and to efficiently suppress a short channel effect.

Furthermore, the short channel effect is efficiently suppressed, so that roll-off characteristics (representing a reduction in the threshold voltage of a transistor in which a gate length is short and a short channel effect is not efficiently suppressed) are improved, resulting in preventing a variation of a threshold voltage.

Furthermore, according to the above embodiments, since impurity implanted into a substrate does not need to be diffused over a long distance, it is possible to reduce the amount of impurity to be implanted, resulting in reducing the manufacturing cost.

The transistor in the above embodiments, for example, is a transistor for a memory cell. However, since a dynamic random access memory (DRAM) is a memory in which transistors are arranged at a comparatively narrow interval, when forming transistors for a DRAM cell, the effect of the invention is further demonstrated.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A method of manufacturing a semiconductor device, the method comprising:
forming a gate electrode on a substrate via a gate dielectric film;
forming a first insulating film on the gate electrode, the first insulating film having a first groove in a central region of the first insulating film; and
forming a halo region in the substrate below a side surface of the gate electrode, by injecting an impurity into the substrate through the first insulating film.

2. The method of claim 1, wherein the forming of the first insulating film includes:
forming a second insulating film around the gate electrode to bury the gate electrode;
forming a second groove on the gate electrode by reducing a height of the gate electrode to be lower than a height of a portion of the second insulating film, the portion being adjacent to the gate electrode;
forming the first insulating film along the bottom and side surfaces of the second groove; and
removing the second insulating film.

3. The method of claim 2, wherein the second insulating film includes a silicon oxide film.

4. The method of claim 1, wherein the first insulating film includes a silicon nitride film.

5. The method of claim 1, wherein the gate electrode includes a stack of a semiconductor film and a metal film.

6. The method of claim 1, further comprising:
forming offset spacers on side surfaces of the gate electrode,
wherein the offset spacers cover an outside surface of the first insulating film, and the impurity is injected into the substrate through the first insulating film and the offset spacer.

7. The method of claim 6, wherein the offset spacers include a silicon nitride film.

8. The method of claim 1, further comprising:
forming a cap film having a bottom surface and a side surface covered with the first insulating film.

9. The method of claim 8, wherein the forming of the cap film includes:
epitaxially growing silicon-based crystal on the substrate;
depositing a third insulating film on the silicon-based crystal and on the first insulating film;
forming the cap film from the third insulating film by removing a portion of the third insulating film on the silicon-based crystal using a planarization process; and
selectively removing the silicon-based crystal by etching the silicon-based crystal under conditions of etching selectivity relative to the substrate.

10. The method of claim 9, wherein the substrate includes Si crystal and the silicon-based crystal includes SiGe crystal or SIC crystal.

11. The method of claim 1, further comprising:
forming a source/drain region in the substrate; and
forming a self-aligned contact connected to the source/drain region.

12. The method of claim 11, wherein the self-aligned contact includes tungsten.

13. The method of claim 11, further comprising:
forming a silicide layer on the source/drain region.

14. A method of manufacturing a semiconductor device, the method comprising:
forming first and second gate electrodes on a substrate via gate dielectric films, respectively;
forming a first insulating film on the first gate electrode, the first insulating film having a first groove in a central region of the first insulating film, and forming a second insulating film on the second gate electrode, the second insulating film having a second groove in central region of the second insulating film; and
forming a first halo region by injecting a first impurity into a first region of the substrate through the second insulating film, the first region being positioned below a side surface of the first gate electrode facing the second gate electrode, and forming a second halo region by injecting a second impurity into a second region of the substrate through the first insulating film, the second region being positioned below a side surface of the second gate electrode facing the first gate electrode.

15. The method of claim 14, wherein the forming of the first and second insulating films includes:
forming a third insulating film around the first and second gate electrodes to bury the first and second gate electrodes;
forming third and fourth grooves on the first and second gate electrodes, respectively by reducing heights of the first and second gate electrodes to be lower than a height of a portion of the third insulating film, the portion being adjacent to the first and second gate electrode;
forming the first insulating film along the bottom and side surfaces of the third groove and forming the second insulating film along a bottom surface and a side surface of the fourth groove; and
removing the third insulating film.

16. The method of claim 15, further comprising:
forming first and second offset spacers on side surfaces of the first and second gate electrodes, respectively,
wherein the third insulating film is formed in contact with side surfaces of the first and second offset spacers,
side surfaces of the third and fourth grooves are upper portions of inner side surfaces of the first and second offset spacers,
the first and second insulating films are formed in contact with the inner side surfaces of the first and second offset spacers,
the first impurity is injected into the first region through the second insulating film and the second offset spacer, and
the second impurity is injected into the second region through the first insulating film and the first offset spacer.

17. The method of claim 14, further comprising:
forming a first cap film having a bottom surface and a side surface covered with the first insulating film and forming a second cap film having a bottom surface and a side surface covered with the second insulating film.

18. The method of claim 17, wherein the forming of the first and second cap films includes:
epitaxially growing silicon-based crystal on the substrate;
depositing a fourth insulating film on the silicon-based crystal and the first and second insulating films;
forming the first and second cap films from the fourth insulating film by removing a portion of the fourth insulating film on the silicon-based crystal using a planarization process; and
selectively removing the silicon-based crystal by etching the silicon-based crystal under conditions of etching selectivity relative to the substrate.

19. The method of claim 18, wherein the substrate includes Si crystal and the silicon-based crystal includes SiGe crystal or SiC crystal.

20. The method of claim 14, further comprising:
forming a source/drain region in the substrate; and
forming a self-aligned contact connected to the source/drain region.
